(19) United States
(12) Patent Application Publication
(10) Pub. No.: US 2025/0329547 A1
(43) Pub. Date: Oct. 23, 2025

(54) SEMICONDUCTOR DEVICE AND METHOD FOR FORMING THE SAME

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR)

(21) Appl. No.: 19/183,909

(22) Filed: Apr. 20, 2025

(30) Foreign Application Priority Data
Apr. 22, 2024 (CN) 202410484334.4

(51) Int. Cl. H01L 21/48; H01L 21/78; H01L 23/31; H01L 25/16

(52) U.S. Cl. CPC H01L 21/4853; H01L 21/78; H01L 23/3128; H01L 25/16

(57) ABSTRACT

A semiconductor device and a method for forming the same are provided. The method includes: providing a semiconductor package including a plurality of contact pads formed on a surface of the semiconductor package; providing a stencil having a plurality of openings; disposing the stencil on the surface of the semiconductor package with the plurality of openings aligned with the plurality of contact pads respectively; forming a plurality of solder bumps on the plurality of contact pads and in the plurality of openings, respectively; and irradiating the plurality of solder bumps with a homogenized laser beam to form a solder interconnection between each of the plurality of solder bumps and a respective one of the plurality of contact pads.

### TECHNICAL FIELD

The present application generally relates to semiconductor technology, and more particularly, to a semiconductor device and a method for forming the same.

### BACKGROUND OF THE INVENTION

The semiconductor industry is constantly faced with complex integration challenges as consumers want their electronics to be smaller, faster and higher performance with more and more functionalities packed into a single device. Laser-assisted bonding (LAB) is a technique that can be used for bonding a semiconductor device to a substrate. However, the LAB may induce stress and damages in the semiconductor device, resulting in low reliability. Therefore, a need exists for a semiconductor device with improved reliability.

### SUMMARY OF THE INVENTION

An objective of the present application is to provide a method for forming a semiconductor device with improved reliability.

According to an aspect of the present application, a method for forming a semiconductor device is provided. The method may include: providing a semiconductor package including a plurality of contact pads formed on a surface of the semiconductor package; providing a stencil having a plurality of openings; disposing the stencil on the surface of the semiconductor package with the plurality of openings aligned with the plurality of contact pads respectively; forming a plurality of solder bumps on the plurality of contact pads and in the plurality of openings, respectively; and irradiating the plurality of solder bumps with a homogenized laser beam to form a solder interconnection between each of the plurality of solder bumps and a respective one of the plurality of contact pads.

According to another aspect of the present application, a method for forming a semiconductor device is provided. The method may include: providing a substrate having a substrate surface, wherein the substrate surface includes at least one bonding region; providing a stencil having at least one opening; disposing the stencil on the substrate surface with the bonding region exposing from the opening of the stencil; disposing at least one solder bump in the bonding region; and irradiating the bonding region with a homogenized laser beam to melt the solder bump.

According to still another aspect of the present application, a semiconductor device is provided. The semiconductor device can be formed according to the aforementioned method.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a diagram illustrating bonding solder bumps on contact pads of a substrate using a laser-assisted bonding (LAB) technique.

FIGS. 2A to 2G are cross-sectional views illustrating various steps of a method for forming a semiconductor device according to an embodiment of the present application.

FIG. 3 is a cross-sectional view illustrating a method for forming a semiconductor device according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

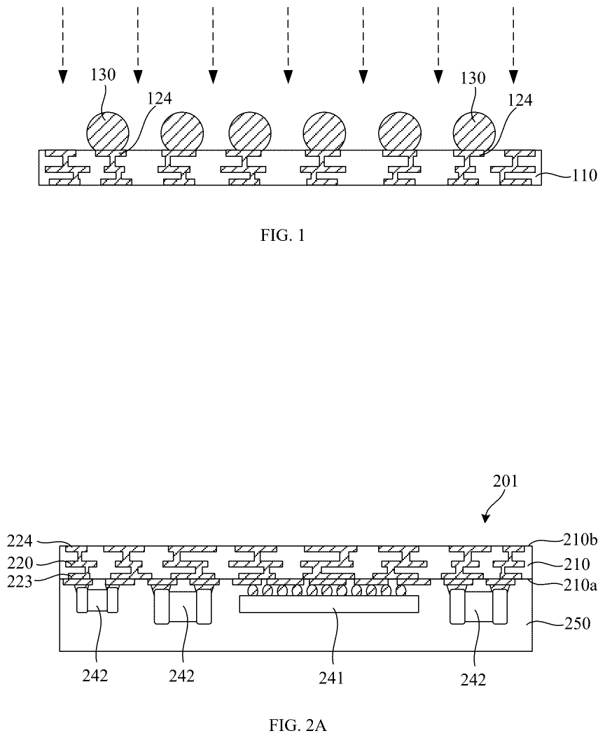

FIG. 1 is a schematic diagram of bonding solder bumps 130 on contact pads 124 of a substrate 110 using a laser-assisted bonding (LAB) technique.

LAB is an advanced surface mount bonding technology in which a homogenized laser beam (that is, a two-dimensional beam, not a one-dimensional beam) is applied to a chip or component in order to establish a metallurgical interconnection with a substrate.

For example, an irradiation area of the homogenized laser beam, as indicated by dashed arrows in FIG. 1, may be the same as a size of the substrate 110. That is, both the solder bumps 130 and the top surface of the substrate 110 are irradiated with the laser beam. The laser beam can apply energy to the solder bumps 130, and heat the solder bumps 130 above the melting point. Then, solder interconnections can be formed between the solder bumps 130 and the contact pads 124 of a substrate 110. However, as the top surface of the substrate 110 is also exposed under the laser beam, heat may be generated inside the substrate 110, resulting in stress and/or warpage in the substrate 110 and possible damages to other electronic components.

To address at least one of the above problems, a method for forming a semiconductor device is provided in an aspect of the present application. In the method, a stencil having a plurality of openings is provided. The stencil is disposed on a surface of a semiconductor package, and the plurality of openings of the stencil are aligned with a plurality of contact pads formed on the surface of the semiconductor package. A plurality of solder bumps are placed on the plurality of contact pads and in the plurality of openings, respectively. Then, the plurality of solder bumps are irradiated with a homogenized laser beam to form a solder interconnection between each of the plurality of solder bumps and a respective one of the plurality of contact pads. As the stencil can reflect some of the laser beam irradiating the surface of a semiconductor package, heat generated inside the semiconductor package can be reduced, thereby reducing stress and/or warpage in the semiconductor package and possible damages to other electronic components in the semiconductor package.

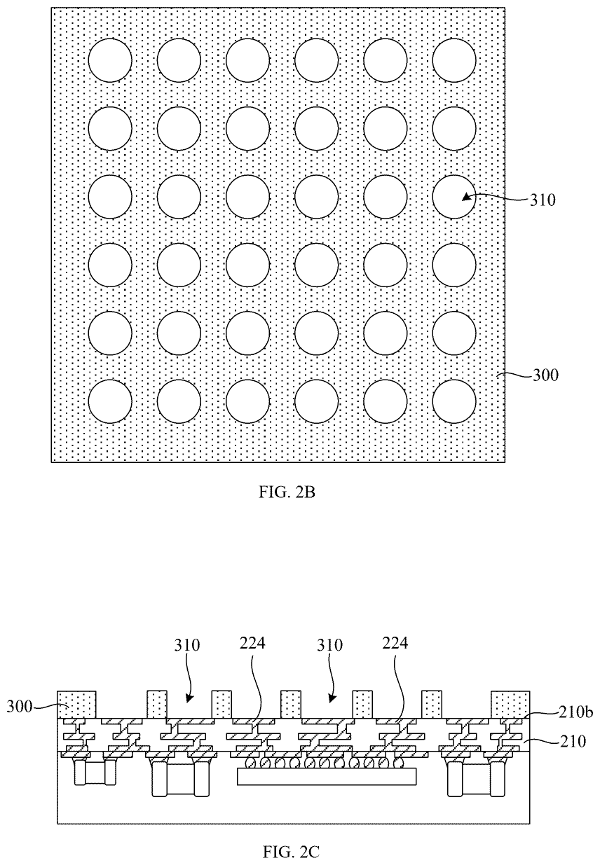

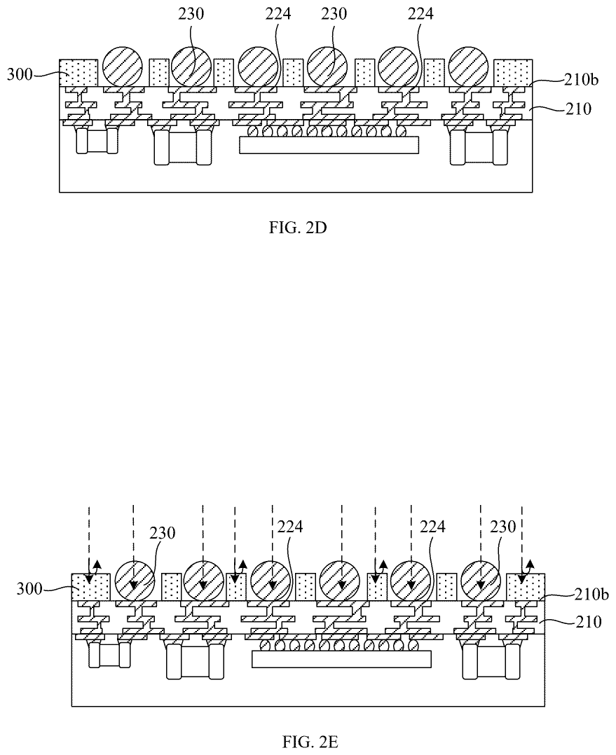

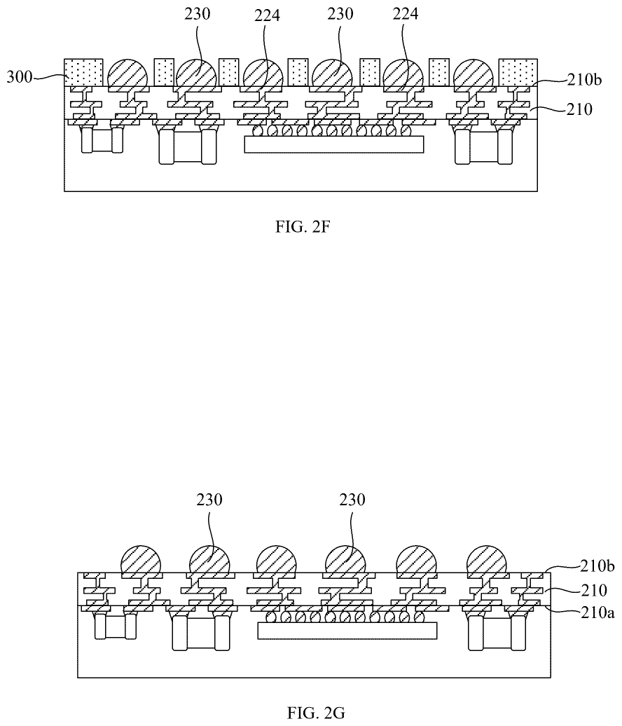

Referring to FIGS. 2A to 2G, various steps of a method for forming a semiconductor device are illustrated according to an embodiment of the present application. In the following, the method will be described with reference to FIGS. 2A to 2G in more details.

Referring to FIG. 2A, a semiconductor package 201 is provided. Specifically, the semiconductor package 201 may include a substrate 210 that provides support and connectivity for electronic components and devices. By way of example, the substrate 210 may include a printed circuit board (PCB), a carrier substrate, a semiconductor substrate with electrical interconnections, a ceramic substrate, a laminate interposer, a strip interposer, a leadframe, or other suitable substrates. The substrate 210 may include any structure on or in which an integrated circuit system can be fabricated.

In the example shown in FIG. 2A, the substrate 210 includes redistribution structures 220 having one or more dielectric layers and one or more conductive layers between and through dielectric layers. The conductive layers may define pads, traces and plugs through which electrical signals or voltages can be distributed horizontally and vertically across the redistribution structures 220. In the example shown in FIG. 2A, the substrate 210 includes a first surface 210a and a second surface 210b opposite to the first surface 210a, and the conductive layers of the redistribution structures 220 include a plurality of first contact pads 223 formed on the first surface 210a of the substrate 210 and a plurality of second contact pads 224 formed on the second surface 210b of the substrate 210. It could be understood that, the redistribution structures 220, the first contact pads 223 and the second contact pads 224 may be implemented in various structures and types, but aspects of the present application are not limited to the above example.

A plurality of electronic components may be mounted on the first surface 210a of the substrate 210 and electrically connected to the first contact pads 223. The electronic components may include any of a variety of types of semiconductor dice, semiconductor packages, or discrete devices. For example, the electronic components may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, a discrete device, etc. In the example of FIG. 2A, the electronic components may include a semiconductor die 241, and multiple discrete devices 242 such as resistors, capacitors, inductors, etc. The semiconductor die 241 is mounted on the first surface 210a of the substrate 210 by a flip-chip bonding technique, such that conductive bumps of the semiconductor die 241 are welded to some of the first contact pads 223. In other examples, the semiconductor die 241 may include bond pads and may be connected to the first contact pads 223 by a wire bonding technique. It could be understood that the semiconductor die 241 and the discrete devices 242 illustrated in FIG. 2A are only examples, and the present application is not limited thereto.

An encapsulant 250 is formed on the first surface 210a of the substrate 210 and encapsulates the electronic components 241 and 242. The encapsulant 250 may be made of polymer composite material, such as epoxy resin with filler, epoxy acrylate with filler, or polymer with proper filler, but the scope of this application is not limited thereto. The encapsulant 250 can protect the electronic components 241 and 242 from external circumstances.

In the example of FIG. 2A, it is only illustrated a single unit of semiconductor package, but the present application is not limited thereto. In some other examples, a strip type of semiconductor packages, i.e., a plurality of semiconductor packages arranged in a strip manner, may be provided. The plurality of semiconductor packages may be isolated from each other by singulation channels. The singulation channels can provide cutting areas to singulate the package strip into individual semiconductor devices.

Referring to FIG. 2B, a stencil 300 having a plurality of openings 310 is provided.

In some embodiments, the layout of the plurality of openings 310 in the stencil 300 may be designed according to positions or shapes of respective contact pads 224 on the second surface 210b of the substrate 210. For example, each of the plurality of openings 310 may have at its bottom a cross-sectional shape which is substantially the same as or larger than a shape of a corresponding contact pad 224, thereby allowing a conductive material such as a solder bump to fully cover the contact pad 224. In some other examples, the cross-sectional shape of the bottom of each of the plurality of openings 310 may be slightly smaller than a shape of its corresponding contact pad 224, resulting in a bleed-resistant seal between the contact pad 224 and the stencil 300.

As the plurality of openings 310 in the stencil 300 may be filled with a solder material and the stencil 300 will be disposed on and removed from the second surface 210b of the substrate 210 in subsequent processes, sidewalls of the plurality of openings 310 should be smooth as possible. In some embodiments, each of the plurality of openings 310 may have a vertically straight sidewall or an inclined wall. For example, each of the plurality of openings 310 may have a truncated shape with a trapezoidal cross section. In some embodiments, a coating layer with anti-stick properties, for example, a solder paste repellent coating may be formed on the sidewalls of the plurality of openings 310, so as to prevent adhesion of the solder material to the stencil 300. It can be appreciated that the shapes of the plurality of openings 310 and a thickness of the stencil 300 may vary according to configurations of the solder bumps to be formed, and are not limited herein.

In the present application, as the stencil 300 may serve as a protection layer to reflect irradiation energy from a homogenized laser beam, the stencil 300 may have a high reflectivity over the spectrum of the laser beam. In some embodiments, the reflectivity of the stencil 300 to the spectrum of the laser beam is at least greater than that of the substrate 210, preferably, greater than 70%, 80%, 90%, or 95%. For example, the stencil 300 may include a metallic material which has a high damping constant, leading to a short distance crossed by the light. For example, the stencil 300 may include Al, Cu, Ag, Au, etc., which has a high reflectivity in a wide range of wavelengths, especially in the infrared (IR) region of the spectrum.

In some embodiments, the stencil 300 may be a single-layer plate made of a metallic material such as Al, Cu, Ag, Au or any combinations thereof. It could be appreciated that the present application is not limited to the above metallic materials, and the stencil 300 may include other materials have a high reflectivity. In some embodiments, the stencil 300 may be a multi-layer laminated structure which has a high reflectivity layer on the upper side. For example, the multi-layer laminated structure may include a top layer having a high reflectivity (e.g., greater than 70%, 80%, 90%, or 95%) and a bottom layer having a low thermal conductivity, such that the top layer can reflect irradiation energy from the laser beam, and the bottom layer can prevent or reduce the transfer of heat to the substrate 210, thereby minimizing thermal impact to the whole semiconductor package. In some embodiments, the thermal conductivity of the bottom layer is at least lower than that of the top layer, for example, lower than the thermal conductivity of Al, Cu, Ag, or Au. By way of example, the top layer may include a metallic material such as Al, Cu, Ag, Au or any combinations thereof, and the bottom layer may include a polymer or ceramic material.

Referring to FIG. 2C and FIG. 2D, the stencil 300 is disposed on the second surface 210b of the substrate 210 with the plurality of openings 310 aligned with the plurality of contact pads 224 respectively, and then a plurality of solder bumps 230 may be formed on the plurality of contact pads 224 and in the plurality of openings 310, respectively.

As the plurality of openings 310 are designed according to positions or shapes of the plurality of contact pads 224, respectively, the plurality of openings 310 can be accurately aligned with the plurality of contact pads 224. The plurality of solder bumps 230 may be formed in the plurality of openings 310 using a stencil printing process, a ball drop process, or an evaporation process. The solder bumps 230 may include eutectic Sn/Pb, high-lead solder, lead-free solder, etc.

In some embodiments, the plurality of solder bumps 230 (for example, solder balls) may be placed on the plurality of contact pads 224 manually or using automated equipment known in the art. The solder bumps 230 can be accurately placed at positions of the contact pads 224 by positioning the solder bumps 230 within the openings 310 of the stencil 300. The openings 310 of the stencil 300 can prevent the solder bumps 230 from deviating from the positions of the contact pads 224.

In some embodiments, the plurality of solder bumps 230 may be formed using a stencil printing process. Specifically, a fluid solder material may be deposited on the stencil 300, and the fluid solder material may flow through the openings 310 onto the contact pads 224. Then, a squeegee may be used to planarize the fluid solder material. The squeegee can press on the stencil 300 to drive the fluid solder material flow into the openings 310 if they are not fully filled with the fluid solder material. The flow of the fluid solder material may depend on the pressure applied by the squeegee, the viscosity of the fluid solder material, and the shape and size of the openings 310. The squeegee can also clean the top surface of the stencil 300, and define the thickness of the fluid solder material filled into the openings 310.

Referring to FIG. 2E and FIG. 2F, the plurality of solder bumps 230 are irradiated with a homogenized laser beam, as indicated by dashed arrows in FIG. 2E, to form a solder interconnection between each of the plurality of solder bumps 230 and a respective one of the plurality of contact pads 224.

In some embodiments, a laser-assisted bonding (LAB) technique may be used to implement the laser irradiation. LAB is an advanced flip chip and surface mount bonding technology in which a homogenized laser beam (that is, a two-dimensional beam, not a one-dimensional beam) is selectively applied to a chip or component in order to establish a metallurgical interconnection with a substrate. For example, a laser homogenizer may be used in LAB to receive a laser beam input via a fiber optic cable, waveguide, or other suitable mechanism, and output a homogenized laser beam over the stencil 300. The homogenizer can smooth out the irregularities in a laser beam profile and create a beam with substantially uniform power across the entire profile of beam. For example, an irradiation area of the homogenized laser beam produced by the homogenizer may be the same as a size of the stencil 300. That is, the stencil 300 and the plurality of solder bumps 230 are all irradiated with the homogenized laser beam.

Specifically, as shown in FIG. 2E, the homogenized laser beam can apply optical energy to the stencil 300 and the plurality of solder bumps 230. The optical energy of the homogenized laser beam can be converted into thermal energy to heat the plurality of solder bumps 230. The solder bumps 230 can be heated above its melting point and reflowed to form a reliable solder interconnection between each of the plurality of solder bumps 230 and a respective one of the plurality of contact pads 224, as shown in FIG. 2F. The heating temperature can be controlled by the irradiation power and time. As the laser beam can provide more localized heat than a reflow oven and is able to reflow solder with a shorter cycle time, there is a reduced likelihood of damaging the electronic components mounted on the substrate 210 during the reflow process. In a specific example, an infrared laser source (for example, having a wavelength ranging between 900 nm and 1100 nm) is employed, and the laser beam is modulated to form a homogeneous spatial power distribution to irradiate the plurality of solder bumps 230 and the stencil 300 for a duration ranging between 1 second and 5 seconds (for example, 2 seconds, 3 seconds, 4 seconds, etc.). However, the present application is not limited to the above example, and the wavelength of the laser beam and the duration of irradiation may vary depending on the intensity of the laser beam, the material and the volume of the solder bumps 230, etc.

On the other hand, the stencil 300 (for example, including Al, Cu, Ag, Au, etc.) may have a high reflectivity over the spectrum of the homogenized laser beam, and can reflect most of the laser beam irradiated thereon. Therefore, less heat may be generated and transferred inside the substrate 210, thereby reducing stress and/or warpage in the substrate 210 and possible damages to electronic components mounted on the substrate 210. Moreover, as the stencil 300 may be made of a metallic material and attached to the substrate 210, the stencil 300 can also provide structural support to the substrate 210 and substantially reduce warpage during the irradiation.

Afterward, referring to FIG. 2F and FIG. 2G, the stencil 300 is removed from the second surface 210b of the substrate 210, leaving the plurality of solder bumps 230 on the substrate 210.

The solder bumps 230 may be electrically connected to any of the electronic components mounted on the first surface 210a of the substrate 210 via the redistribution structures formed in the substrate 210. In a case where the semiconductor device shown in FIG. 2G is mounted on an external device or substrate such as a printed circuit board (PCB), the solder bumps 230 may be used for electrically connecting the semiconductor device to the external device or substrate.

In some embodiments, as described above, the semiconductor package may include a plurality of semiconductor devices arranged in a strip manner, and the package strip may be singulated into individual semiconductor devices. For example, a laser cutting process, a saw blading, an etching process, or any other suitable process known in the art can be employed to singulate the package strip into individual semiconductor devices through the singulation channels.

In the embodiment described with reference to FIGS. 2A to 2G, the method of the present application can be used to form the solder bumps on the contact pads. However, the present application is not limited thereto. In some other embodiments, the method of the present application can be used to form any solder interconnections in a semiconductor device.

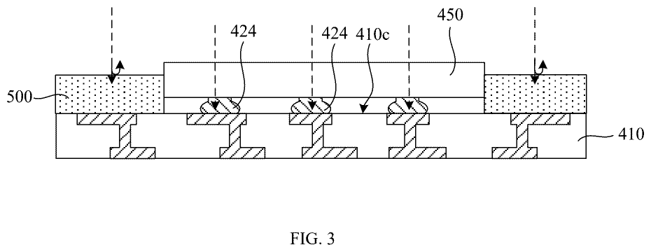

Referring to FIG. 3, a method for forming a semiconductor device is illustrated according to another embodiment of the present application. The method may be used to bond a semiconductor die 450 on a substrate 410.

Specifically, the substrate 410 is first provided. The substrate 410 may include redistribution structures similar as that of the substrate 210 shown in FIG. 2A. The substrate 410 may include a bonding region 410c, i.e., the center part of its upper surface as shown in FIG. 3. Then, a stencil 500 having an opening is provided, and the stencil 500 is disposed on the upper surface of the substrate 410 with the bonding region 410c exposing from the opening of the stencil 500. Afterward, the semiconductor die 450 having a plurality of solder bump 424 is provided. The semiconductor die 450 is placed on the substrate 410 with the solder bump 424 contacting with contact pads formed in the bonding region 410c. Afterward, the bonding region 410c may be irradiated with a homogenized laser beam, as indicated by dashed arrows in FIG. 3, to form a solder interconnection between each of the plurality of solder bumps and a respective one of the plurality of contact pads. As shown in FIG. 3, the homogenized laser beam can pass through the semiconductor die 450 and apply energy to the solder bumps to form the solder interconnection. Meanwhile, the stencil 500 (for example, including Al, Cu, Ag, Au, etc.) may have a high reflectivity over the spectrum of the homogenized laser beam, and reflects most of the laser beam irradiated thereon. The method described with reference to FIG. 3 may share characteristics with the method described with reference to FIGS. 2A to 2G, and will not be elaborated herein.

According to another aspect of the present application, a semiconductor device is provided. The semiconductor device may be formed by any of the aforementioned methods. For example, the semiconductor device may be the same as the semiconductor device shown in FIG. 2G, or the semiconductor device shown in FIG. 3, and will not be repeated herein.

The discussion herein included numerous illustrative figures that showed various portions of a semiconductor device and a method for making the same. For illustrative clarity, such figures did not show all aspects of each example device. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor device, comprising:
providing a semiconductor package comprising a plurality of contact pads formed on a surface of the semiconductor package;
providing a stencil having a plurality of openings;
disposing the stencil on the surface of the semiconductor package with the plurality of openings aligned with the plurality of contact pads respectively;
forming a plurality of solder bumps on the plurality of contact pads and in the plurality of openings, respectively; and
irradiating the plurality of solder bumps with a homogenized laser beam to form a solder interconnection between each of the plurality of solder bumps and a respective one of the plurality of contact pads.

2. The method of claim 1, wherein the semiconductor package comprises:
a substrate having a first surface and a second surface opposite to the first surface;
at least one electronic component mounted on the first surface of the substrate; and
an encapsulant formed on the first surface of the substrate and encapsulating the electronic component,
wherein the plurality of contact pads are formed on the second surface of the substrate.

3. The method of claim 1, wherein the stencil comprises a material with a high reflectivity.

4. The method of claim 3, wherein the stencil comprises Al, Cu, Ag, or Au.

5. The method of claim 1, wherein the stencil is a multi-layer laminated structure comprising a top layer having a high reflectivity and a bottom layer having a low thermal conductivity.

6. The method of claim 1, wherein irradiating the plurality of solder bumps with the homogenized laser beam comprises:
irradiating the plurality of solder bumps with an infrared laser beam.

7. The method of claim 1, wherein irradiating the plurality of solder bumps with the homogenized laser beam comprises:
irradiating the plurality of solder bumps with the homogenized laser beam for a duration ranging between 1 second and 5 seconds.

8. The method of claim 1, further comprising:
removing the stencil from the surface of the semiconductor package.

9. The method of claim 1, wherein the semiconductor package comprises a plurality of semiconductor devices arranged in a strip manner, and the method further comprises:
singulating the semiconductor package into individual semiconductor devices.

10. A method for forming a semiconductor device, comprising:
providing a substrate having a substrate surface, wherein the substrate surface comprises at least one bonding region;
providing a stencil having at least one opening;
disposing the stencil on the substrate surface with the bonding region exposing from the opening of the stencil;
disposing at least one solder bump in the bonding region; and
irradiating the bonding region with a homogenized laser beam to melt the solder bump.

11. The method of claim 10, wherein the stencil comprises a material with a high reflectivity.

12. The method of claim 11, wherein the stencil comprises Al, Cu, Ag, or Au.

13. The method of claim 10, wherein the stencil is a multi-layer laminated structure comprising a top layer having a high reflectivity and a bottom layer having a low thermal conductivity.

14. The method of claim 10, wherein irradiating the bonding region with the homogenized laser beam comprises:
irradiating the bonding region with an infrared laser beam.

15. The method of claim 10, wherein irradiating the bonding region with the homogenized laser beam comprises:
irradiating the bonding region with the homogenized laser beam for a duration ranging between 1 second and 5 seconds.

16. The method of claim 10, further comprising:
removing the stencil from the substrate surface.

17. A semiconductor device, wherein the semiconductor device is formed using the method of claim 1.
